(19) United States
(12) Patent Application Publication
(10) Pub. No.: US 2024/0151507 A1
(43) Pub. Date: May 9, 2024

(54) POSITION SENSOR SYSTEM

(71) Applicant: Infineon Technologies AG, Neubiberg (DE)

(72) Inventor: Gernot BINDER, Klagenfurt (AT)

(21) Appl. No.: 18/493,545

(22) Filed: Oct. 24, 2023

(30) Foreign Application Priority Data
Nov. 3, 2022 (DE) 102022129102.2

(51) Int. Cl. G01B 7/00; G01R 17/00

(52) U.S. Cl. CPC G01B 7/003; G01R 17/00

(57) ABSTRACT

An example of a position sensor system includes a magnet arrangement with at least one north pole and one south pole each. A first sensor is spaced apart from the magnet arrangement, wherein the first sensor includes four magnetoresistive elements interconnected in a first full-bridge circuit and sensitive for a first field direction, wherein the two magnetoresistive elements of a first branch of the first full-bridge circuit are arranged at a distance of more than 0.5 mm apart and wherein the two magnetoresistive elements of a second branch of the second full-bridge circuit are arranged at the distance apart. The magnet arrangement and the sensor can be moved relative to each other in a measuring direction.

### CROSS-REFERENCE TO RELATED APPLICATION

This application claims priority to German Patent Application No. 102022129102.2 filed on Nov. 3, 2022, the content of which is incorporated by reference herein in its entirety.

### TECHNICAL FIELD

Example implementations relate to a position sensor system having a sensor and a magnet arrangement.

### BACKGROUND

Position sensor systems for linear position and motion detection have numerous applications.

Such position sensor systems are often based on the measurement of magnetic fields, for example using linear Hall and 3D magnetic-field sensors which measure the magnetic field of a magnetic field array of known geometry. Conventional linear Hall and 3D magnetic-field sensors are single-cell sensors and therefore have a lower robustness to stray fields. An external magnetic field that may be present interferes with the field of the magnetic field to be measured and can therefore lead to false position information.

Such problems can arise, for example, in an electric drive train of a vehicle in which the electric motors used to drive the vehicle sometimes generate magnetic fields of considerable strength.

There is a need to improve position sensor systems.

### SUMMARY

This need is satisfied using the subject matter of the patent claims.

A position sensor system includes, for example, a magnet arrangement with at least one north pole and one south pole each. A first sensor is spaced apart from the magnet arrangement, wherein the first sensor includes four magnetoresistive (MR) elements interconnected in a first full-bridge circuit and sensitive for a first field direction, wherein the two magnetoresistive elements of a first branch of the first full-bridge circuit are arranged at a distance of more than 0.5 mm apart and wherein the two magnetoresistive elements of a second branch of the second full-bridge circuit are arranged at this distance apart. The magnet arrangement and the sensor can be moved relative to each other in a measuring direction.

The distance between the magnetoresistive elements within a branch causes a compensation of stray fields already within the bridge circuit itself, which are superimposed on the two magnetoresistive elements in the same phase and at the same strength and therefore compensate each other due to the measuring principle of the bridge circuit. At the same time, the magnetoresistive elements of the bridge circuit acting in the same direction can be at the same position with respect to the phase position of the magnetic field to be measured. This allows the measurement result to be more accurate than in other solutions that have a spatial offset between the two branches and thus a phase difference of the magnetic field between the positions where the magnetoresistive elements are located within the separate branches.

### BRIEF DESCRIPTION OF THE DRAWINGS

Some examples of systems and/or methods are described in more detail in the following with reference to the accompanying figures, purely as examples. In the drawings:

FIG. 1 shows two example implementations of a position sensor system;

FIG. 2a shows an example implementation of a sensor for a position sensor system;

FIG. 2b shows an example implementation of a first sensor and a second sensor for a position sensor system;

FIG. 2c shows two examples of a layout of the sensors of FIGS. 2a and 2b;

FIGS. 3a to 3e the representations of magnetic field components of an example implementation of a position sensor system and the resulting measured values as well as the position determination errors; and

FIGS. 4a and 4b shows a conventional position sensor system and a representation of its measurement error.

### DETAILED DESCRIPTION

Some examples are now described in more detail with reference to the accompanying figures. However, other possible examples are not limited to the features of these implementations described in detail. These can have modifications of the features as well as equivalents and alternatives to the features. In addition, the terminology that is used here to describe specific examples, is not intended to be limiting for other examples.

Identical or similar reference signs refer throughout the description of the figures to the same or similar elements or features, which may each be implemented identically or in modified form although they provide the same or a similar function. In the figures, the thicknesses of lines, layers and/or regions may be shown exaggerated for the sake of clarity.

If two elements A and B are combined using an “or”, this should be understood to mean that all possible combinations are disclosed, e.g., only A, only B, as well as A and B, unless explicitly defined otherwise in individual cases. An alternative formulation that can be used for the same combinations is “at least one of A and B” or “A and/or B”. An equivalent formulation applies to combinations of more than two elements.

If a singular form (e.g., “a,” “an,” and “the”) is used and the use of only a single element is neither explicitly nor implicitly defined as mandatory, then other examples may also use a plurality of elements to implement the same function. If a function is described in the following as being implemented using a plurality of elements, further examples may implement the same function by using a single element or a single processing entity. It also goes without saying that the use of the terms “comprises”, “comprising”, “has” and/or “having” precisely defines the presence of the specified features, integers, steps, operations, processes, elements, components and/or a group of the same, but not the presence or the addition of one or more other features, integers, steps, operations, processes, elements, components and/or a group of the same.

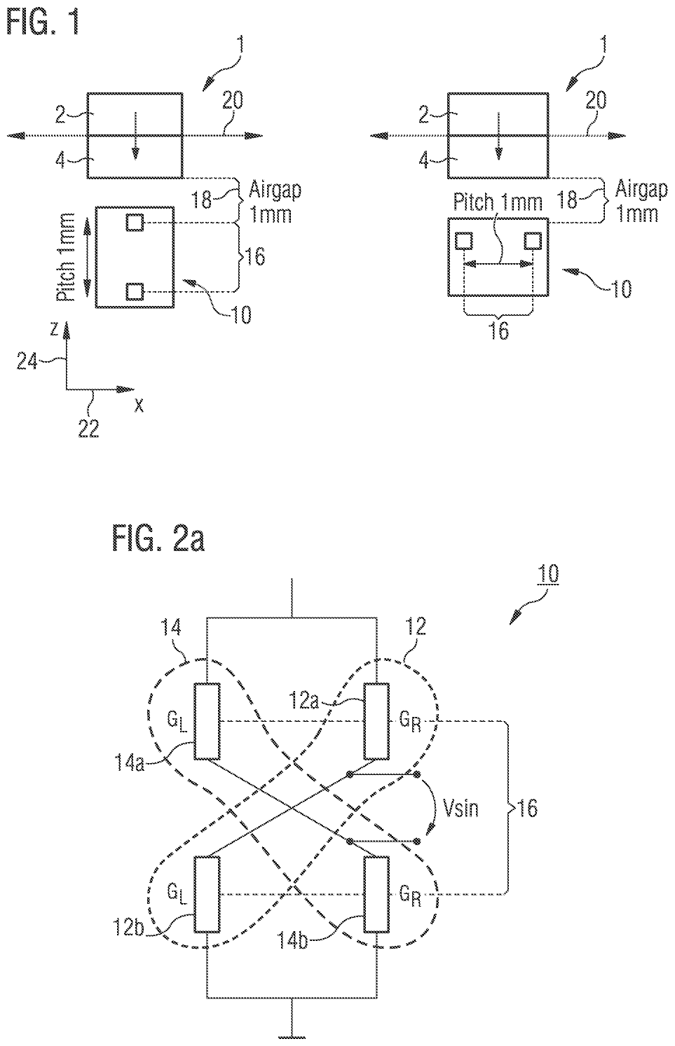

FIG. 1 shows two example implementations of a position sensor system.

The position sensor system comprises a magnet arrangement 1 with at least one north pole 2 and one south pole 4 each. In the example implementation of FIG. 1, a system with a single dipole magnet 1 is shown as a possible implementation of a system for absolute position determination. In further example implementations, however, magnet arrangements having multiple alternating north and south poles can also be used, which have a greater length and can be used both as a magnet arrangement for linear position determination as well as for angle determination.

In the following, both implementations with one sensor and implementations with two sensors will be discussed, wherein initially only a single first sensor 10 is considered to explain the operating principle. The first sensor 10 is spaced apart from the magnet arrangement 1. The minimum distance 18 from sensor 10 to the magnet arrangement 1 is also referred to as the air gap. The magnet arrangement 1 and the sensor 10 are movable relative to each other along a measuring direction 20 and the relative position between the magnet arrangement 1 and sensor 10 is to be determined by the position sensor system. For this purpose, the sensor measures properties such as individual components of the magnetic field and an optional evaluation device or evaluation logic uses this to determine the relative position.

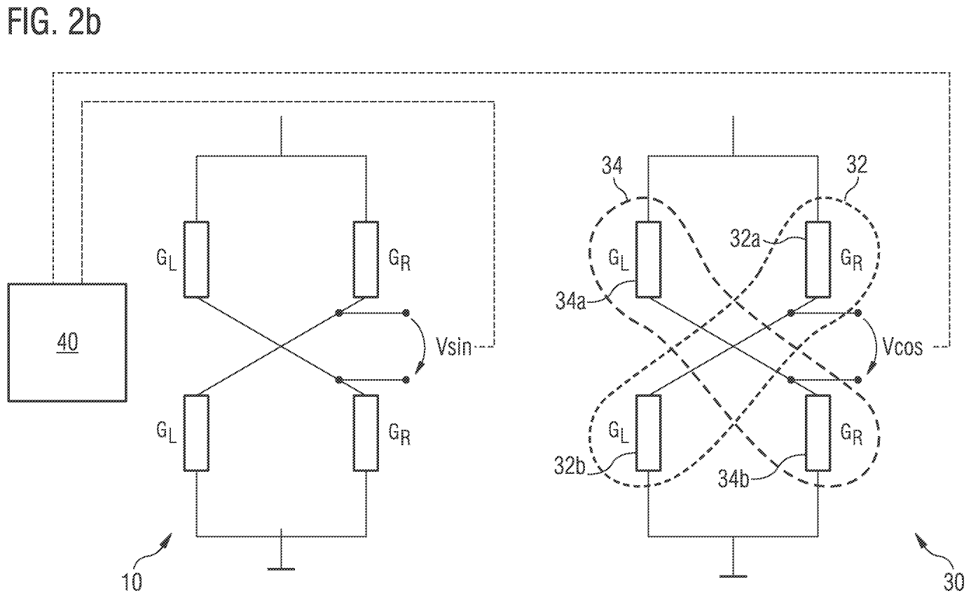

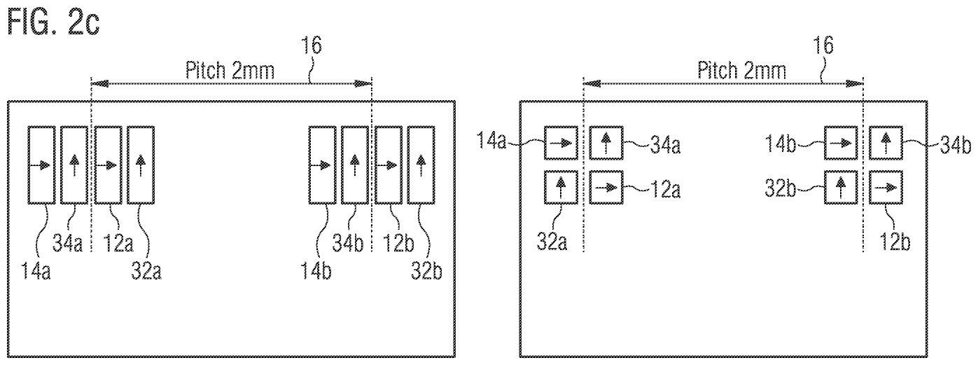

The first sensor 10 is shown with its elements in a principle sketch in FIG. 2a and has four magnetoresistive elements 12a, 12b, 14a and 14b interconnected in a first full-bridge circuit. The first sensor 10 is sensitive for a first field direction 22, which is why the fixed magnetized layers (pinned layers) in all magnetoresistive elements 12a, 12b, 14a and 14b of the sensor 10 have a magnetization in a corresponding direction. The two magnetoresistive elements 12a, 12b of a first branch 12 of the first full-bridge circuit are arranged at a distance 16 of more than 0.5 mm apart. Also, the two magnetoresistive elements 14a, 14b of a second branch 14 of the second full-bridge circuit are arranged at the distance 16 apart from each other.

In contrast to conventionally, in the sensor of FIG. 2a, the magnetoresistive elements 12a, 12b and 14, 14b are each spaced apart from each other within a branch on a macroscopic scale and by more than 0.5 mm. The macroscopic scale is understood to mean the scale on which a significant change in the magnetic field results, which is therefore associated with the dimension of the magnet 1. In contrast, the microscopic scale is understood to mean the scale that describes the structural size of the semiconductor devices and, in particular, of the magnetoresistive elements. For example, the two scales may differ by a factor of 10 or more. Examples of other possible distances 16 are distances greater than or equal to 0.8 mm, 1.0 mm, 1.5 mm, 2.0 mm, 2.5 mm or 3.0 mm. Such a distance causes compensation of signal components of external stray fields already within the full-bridge circuit itself, because stray fields are superimposed on the fields of the magnet arrangement to be measured at both magnetoresistive elements within a branch in the same phase and at the same strength, and therefore their components compensate each other in the voltage read off between the branches of the full-bridge circuit due to the measuring principle of the full-bridge circuit. At the same time, in a sensor 10 of this type the magnetoresistive elements of the full-bridge circuit acting in the same direction are located substantially (on a macroscopic scale) at the same position with respect to the phase position of the magnetic field to be measured. This allows the measurement result to be more accurate than in other solutions that, for example, have a spatial offset between the two branches (half-bridges) and thus a phase difference of the magnetic field at the respective locations of the magnetoresistive elements within the individual branches. Compared to solutions in which the measurement results of two independent sensors are subtracted from each other to compensate for the stray fields, the number of magnetoresistive elements can be halved and the switching complexity in both the analog and the digital signal processing can be reduced.

If the spatial separation of the magnetoresistive elements in the individual branches of the full-bridge circuit is on the order of magnitude mentioned above, the distance is large enough for the aforementioned advantageous effects, but still small enough so that all magnetoresistive elements of the sensor can optionally be accommodated in a common housing. This can result in an easy-to-handle, low-cost, yet robust implementation.

The left-hand illustration in FIG. 1 shows an example implementation in which the distance 16 between the magnetoresistive elements within a branch of the full-bridge circuit is perpendicular to the measuring direction 20.

The right-hand illustration in FIG. 1 shows an example implementation in which, according to one of the preceding claims, the distance 16 between the magnetoresistive elements within a branch of the full-bridge circuit is parallel to the measuring direction 20.

According to further example implementations, however, any other orientations of the distance 16 relative to the measuring direction 20 are also possible.

According to some example implementations, the four magnetoresistive elements 12a, 12b, 14a, 14b are based on the magnetic tunnel resistance (e.g., TMR). Due to their high sensitivity, for example, a small dipole magnet or a small magnet arrangement can be used to obtain a compact system that can be used in many installation situations. According to other example implementations, the four magnetoresistive elements 12a, 12b, 14a, 14b may also be based on other effects, for example on the anisotropic magnetoresistive effect (AMR), or the giant magnetoresistance (GMR).

According to a further example implementation, due to the high sensitivity of the sensor, the magnet can consist of a comparatively inexpensive material, for example, a sintered ferrite material.

At high sensor sensitivities, a distance between the magnet arrangement 1 and the first sensor 10 on a macroscopic scale can also be chosen larger than when sensors with lower sensitivity are used. In the example implementation shown, a minimum distance 18 between the magnet arrangement 1 and the first sensor 10 is one millimeter. This value can be varied according to the requirements or the available magnetic field strength, and in further example implementations, for example, may be greater than 0.5 mm, greater than 0.8 mm or greater than 1.0 mm.

FIG. 2b shows an example implementation of a sensor system for a position sensor system with two sensors sensitive to different magnetic field components. The first sensor 10, which has been discussed by reference to FIG. 2a, is supplemented by a second sensor 30, which is almost identical in structure. In other words, the second sensor 30 also has four magnetoresistive elements interconnected in a second full-bridge circuit and sensitive for a second field direction 24 (see FIG. 1), wherein the two magnetoresistive elements 32a and 32b of a first branch 32 of the second full-bridge circuit are arranged at the distance 16 (pitch) apart and wherein the two magnetoresistive elements 34a and 34b of a second branch 34 of the second full-bridge circuit are also arranged at the distance 16 apart. In the illustrated example implementation, the second field direction 24 is the z-direction and stands perpendicular to the first field direction 22, the x-direction.

The x- and z-direction span a plane parallel to the plane of the chip of the sensors, assuming they are in-plane sensors. The second sensor 30 measures the second field direction. The measuring direction 20 runs in the plane that is spanned by the first field direction 22 and the second field direction 24.

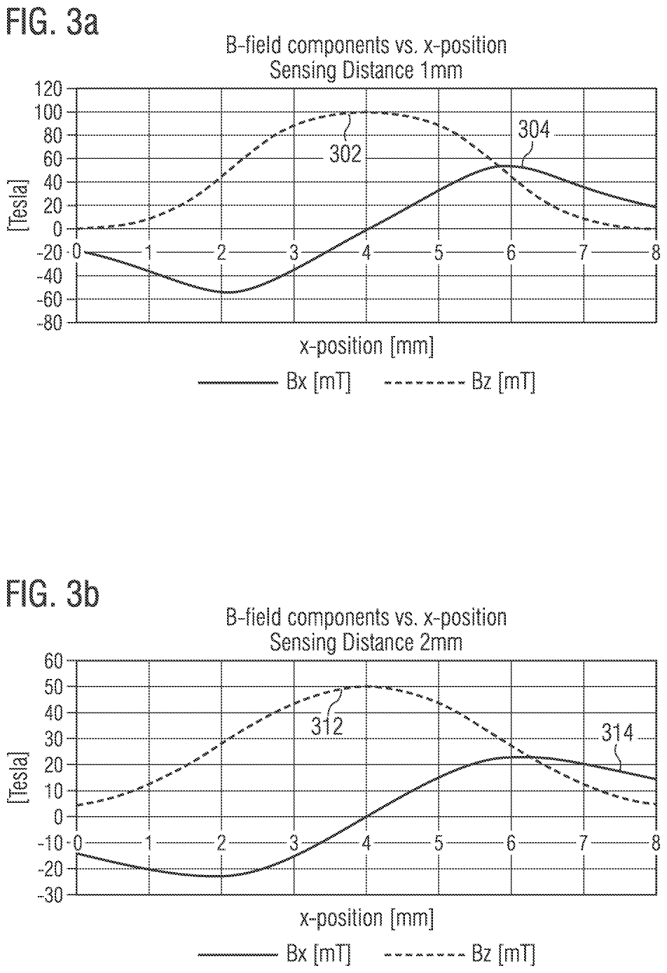

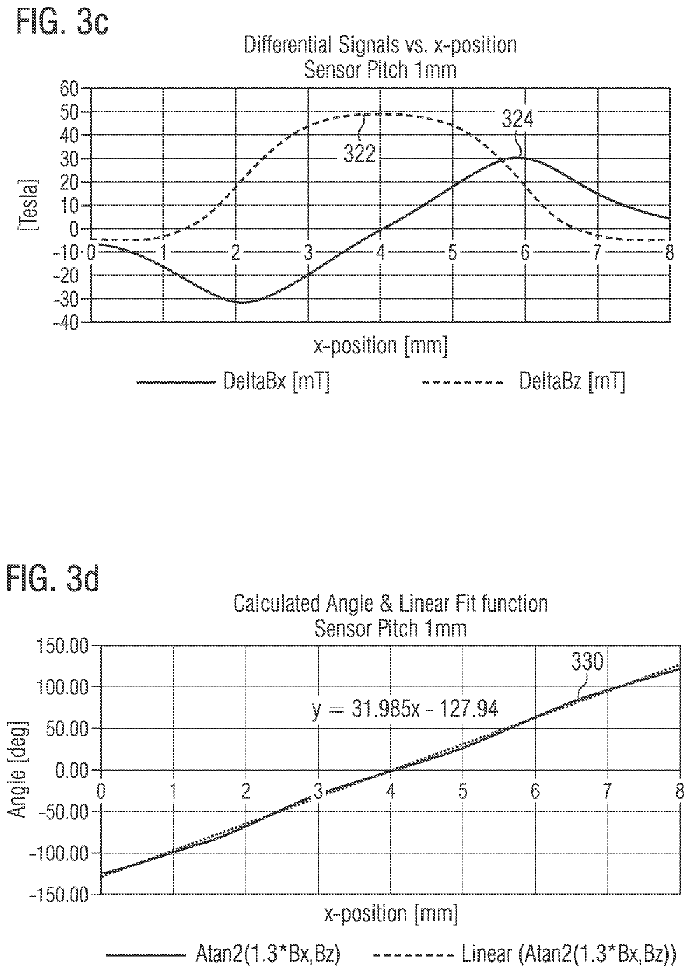

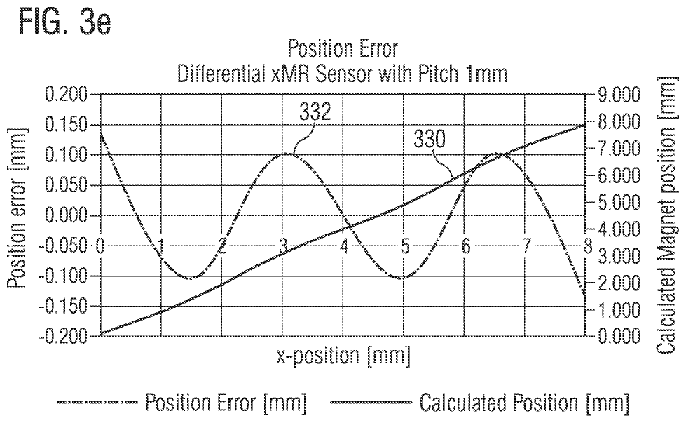

The additional information of the second field direction can be used using the known CORDIC algorithm to resolve an ambiguity in the result of the measurements of individual field components (in the present case the x-direction and the z-direction) and thereby to double the range which is accessible to the unique linear position determination, as can be seen below from FIGS. 3a to 3e.

In the position sensor system with the sensors shown in FIG. 2b, in the macroscopic scale for the left-hand example implementation of FIG. 1 the magnetoresistive elements of the first branch 12 of the first sensor 10 are located in the measuring direction 20 substantially at the same position as the magnetoresistive elements of the first branch 32 of the second sensor 30 and possibly on the same substrate or in the same chip. This is shown in FIG. 2c in a schematic illustration showing the sensor arrangement rotated by 90 degrees.

Physically, therefore, the magnetoresistive elements 12a, 12b, 14a, 14b, 32a, 32b, 34a, 34b of the sensor arrangement of FIG. 2b (for example, xMR resistors) are arranged in two nested together and spatially distributed Wheatstone bridges (full-bridge circuits). The reference layer magnetization of the MR elements of the second sensor 30 or the second bridge is rotated by plus 90° or minus 90° relative to the reference layer magnetization of the MR elements of the first sensor 10 or the first bridge. The full-bridge circuits are nested with each other in the layout. In this way, they occupy substantially the same spatial position with respect to the phase of the magnetic field.

When the sensors are exposed to a magnetic field, they emit two electrical signals (Vsin and Vcos) that are phase-shifted by 90 degrees to each other (at least in the case of a magnet arrangement of multi-pole strip magnets with alternating patterns of north and south poles, or in the case of a single dipole magnet). Within the evaluation circuit 40, for example, the signals can first be digitized with an ADC and then processed in a DSP with a CORDIC algorithm. An angle is then calculated from the two input signals using the atan2 function.

Due to the differential bridge configuration, the external homogeneous magnetic stray fields cancel each other out as previously explained. Using a linear fitting of the measured angle information, as shown in FIG. 3d, it is possible to calculate back directly to the actual position of the magnet.

In the implementation of the left-hand illustration of FIG. 1, the sensor 10 is aligned such that the sensor elements or magnetoresistive elements are arranged in a different air gap (e.g., in a different z-position) relative to the magnet surface. In a second implementation (right-hand illustration in FIG. 1), the sensor elements or magnetoresistive elements are arranged in the same air gap, but in different x-positions. The magnet arrangement consists of a simple block or cylinder magnet. This can be magnetized/aligned in the x- or z-direction.

The evaluation circuit 40 schematically shown in FIG. 2b thus calculates a relative position between the magnet arrangement 1 and the first sensor 10 in the measuring direction 20, based on a first measured value (Vsin) between the two branches 12, 14 of the first full-bridge circuit of the first sensor 10 and on a second measured value (Vcos) between the two branches 32, 34 of the second full-bridge circuit of the second sensor 30.

The magnetic field components at the positions of the magnetoresistive elements of the sensors 10 and 30 as well as the resulting measured variable are shown in FIGS. 3a to 3c. The position calculated from this by the evaluation circuit 40 and its error is illustrated in FIGS. 3d and 3e.

FIG. 3a shows the B-field components 302 (Bz) and 304 (Bx) at the position of the magnetoresistive elements 12a, 4a, 32a, 34a that are closer to the magnet 1 (1 mm apart). FIG. 3b shows the B-field components 312 (Bz) and 314 (Bx) at the position of the magnetoresistive elements 12b, 14b, 32b, 34b that are further away from the magnet 1 (2 mm apart). FIG. 6c shows the resulting differential signals 322 and 324, e.g., the output signals Vsin and Vcos, which correspond to the differential bridge output of the two sensors 10 and 30 or the two Wheatstone bridges respectively.

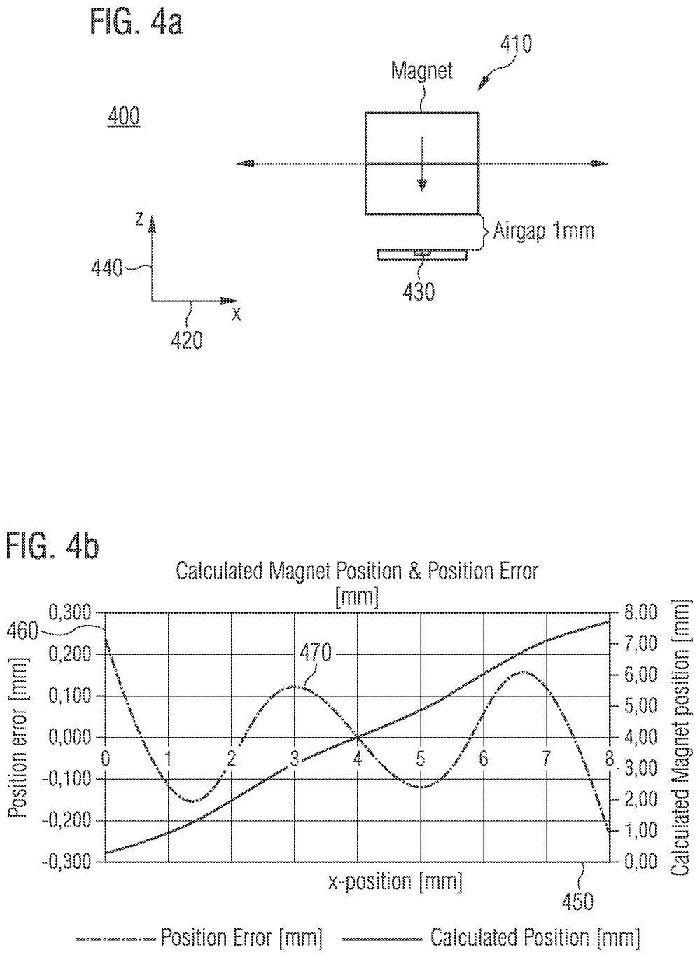

From the differential signals 322 and 324, the evaluation circuit 40 calculates an angle 330 using the arc tangent function, which is plotted against the relative position in FIG. 3d. A linear fitting function is applied to obtain the slope and axis intersection values of the graph of the angle 330. Based on these parameters, the position of the magnet is calculated for the measured values of Vsin and Vcos. FIG. 3e shows the calculated magnet position 330 and the corresponding position error 332. The maximum position error of the example implementation considered is +−138 μm or +−1.7% of the measurement range of 8 mm. The measuring principle is stray-field robust, temperature-independent and the error is significantly smaller than the position error of a standard 3D sensor solution, which is shown in FIGS. 4a and 4b for comparison and which has an error of +−241 μm.

FIGS. 4a-4b show for comparison a conventional position sensor system and an illustration of its measurement error.

For comparison, FIG. 4a illustrates a conventional measuring system without spatially separated sensitive elements within the branches of a bridge circuit.

As in the configuration underlying the analyses of FIGS. 3a to 3e, an axially magnetized cylinder magnet moves in the x-direction 420 from an assumed −4 mm to +4 mm (8 mm range of motion). A sensor 430 is located at a distance of 1 mm. For example, a typical lateral Hall sensor would react to the Bz field in the direction of the z-direction 440 and thus to the field perpendicular to the plane of the Hall sensor. However, this signal would be ambiguous in comparison to the range of motion of 8 mm. In the case of a 1D sensor, the measurement range would therefore have to be reduced from 8 mm to only 4 mm (0 to 4 mm).

With a conventional 3D sensor, in a similar way to the description in FIGS. 2a to 3e, the Bx and Bz signal can be combined and an angle calculated using the arc tangent, which is representative of the position of the magnet, and calculate the position by applying a linear fitting function for the angle.

For the comparison arrangement with a 3D sensor, FIG. 4b shows the measured magnet position on the Y-axis 460 as a function of the actual position, plotted on the X-axis 450, and the corresponding position error 470. The maximum error is +−241 μm or +−3% of the measurement range, hence it is significantly greater than the measurement accuracy of the example implementations described by reference to FIGS. 1 to 3. As an additional disadvantage, this position measurement is also not stray-field stable, which would further reduce the accuracy in many real-world installation situations and underlines the advantages of the example implementations described in the foregoing.

Example implementations of position sensor systems can be used in powertrains of motor vehicles but also in many other applications. These can enable reliable, accurate and stray-field insensitive (absolute) position or angle measurement and can therefore be used for many applications in automotive, industrial and consumer electronics. Thanks to their small size, they are also suitable for consumer applications, such as in smartphones. One possible scenario is the application in a smartphone camera, where small voice coil actuators (a magnet is moved by the Lorentz force when a coil is energized) are used to move the lens and, in combination with a magnetic position sensor, enable precise auto-focusing.

The proposed (e.g., linear) position sensor systems are robust to stray fields and among other advantages compared to modern HALL single-cell solutions, they have an extended detection range.

The sensor arrangement can be implemented by xMR elements, which are connected in two spatially distributed Wheatstone bridges. It measures the two magnetic field components in the plane. From the two differential bridge signals, angle information representative of the magnet position can be calculated. By linear fitting of this angle, the true position of the magnet can be calculated—this method is independent of temperature.

In the sensor arrangement, two differential Wheatstone bridges can be arranged in a nested layout. The reference layer magnetization of the MR stacks of the second bridge is shifted by plus 90° or minus 90° compared to the reference layer magnetization of the MR resistors of the first bridge. The bridges are nested with each other in the layout. In this way, they occupy substantially the same spatial position in terms of phase.

This layout can enable a stray-field robust, absolute linear position measurement with an extended detection range compared to the 1D sensor. The measurement is temperature-independent (since the atan2 function used for the position determination only takes into account the signal ratio, but not the absolute magnitude (vector length)). The high xMR sensitivities can enable cost-effective magnet solutions and, as a result, absolute position sensing over larger extended ranges is achieved thanks to the simple magnet design (no multi-pole magnets). In addition, the sensor arrangement can be realized in a small package.

A cost-effective position sensor could be constructed based on differential xMR technology for absolute linear position sensing according to the considerations above. For example, the sensor elements can have a separation of only 1 mm and can therefore be integrated in a common housing with a small footprint. The sensor array can consist of two nested and spatially distributed Wheatstone bridges (two sensors). Each bridge measures a field component of the magnetic field in the plane. By calculating the angle from the two differential bridge signals of the respective sensors using the arc tangent function, a unique and temperature-independent measurement signal is obtained that is free of stray fields. From this angle information and a linear fitting function, the true position of the magnet and the moving object is calculated with high accuracy and the result is robust to stray fields.

Example implementations of position sensor systems are very well suited to a stray-field robust linear position detection and for the measurement of angles outside a shaft.

The output signal of the well-known CORDIC algorithm can be linearized for a linear position measurement, e.g., with a linear fitting function.

Using the vernier principle, a unique angle can also be determined over a full mechanical revolution of a shaft if a magnet arrangement with multiple alternating magnetic poles is used to generate the magnetic field to be measured.

Thanks to the high sensitivity of linear TMR components, low-cost magnets (sintered ferrites) can be used in corresponding example implementations, while still allowing a large air gap. This can enable cost-effective and highly flexible system designs.

The aspects and features which are described together with a specific one of the previously outlined examples can also be combined with one or more of the other examples in order to replace an identical or similar feature of this other example or to introduce the feature into the other example as an addition.

Steps, operations or processes of the evaluation circuit 40 can be executed, for example, by programmed computers, processors or other programmable hardware components. Other examples may also include computers, processors, control units, (field) programmable logic arrays ((F)PLAs), (field) programmable gate arrays ((F)PGAs), graphics processors (GPUs), application-specific integrated circuits (ASICs), integrated circuits (ICs), or single-chip systems (System-on-a-Chip, SoC) which are programmed to execute the steps of the above described methods in the evaluation circuit 40.

In addition, the following claims are hereby incorporated into the detailed description, where each claim can stand for a separate example in itself. It is also important to note that, although a dependent claim in the claims may relate to a specific combination with one or more other claims, other examples may also comprise a combination of the dependent claim with the subject matter of any other dependent or independent claim. Such combinations are explicitly proposed herewith, except where it is specified in individual cases that a certain combination is not intended. In addition, features of a claim should also be included for any other independent claim, even if this claim is not directly defined as being dependent on this other independent claim.

### Aspects

The following provides an overview of some Aspect s of the present disclosure:

Aspect 1: A position sensor system, comprising: a magnet arrangement having at least one north pole and one south pole; and a first sensor spaced apart from the magnet arrangement, wherein the first sensor comprises four magnetoresistive elements interconnected in a first full-bridge circuit and sensitive to a first field direction, wherein a first two magnetoresistive elements of a first branch of the first full-bridge circuit are arranged at a distance apart of more than 0.5 mm and wherein a second two magnetoresistive elements of a second branch of the first full-bridge circuit are arranged at the distance apart, wherein the magnet arrangement is movable relative to the first sensor in a measuring direction, or the first sensor is movable relative to the magnet arrangement in the measuring direction.

Aspect 2: The position sensor system as recited in Aspect 1, wherein the four magnetoresistive elements are based on a magnetic tunnel resistance.

Aspect 3: The position sensor system as claimed in any of Aspects 1-2, further comprising: a second sensor spaced apart from the magnet arrangement, wherein the second sensor comprises another four magnetoresistive elements interconnected in a second full-bridge circuit and sensitive to a second field direction, wherein a first two magnetoresistive elements of a first branch of the second full-bridge circuit are arranged at the distance apart and wherein a second two magnetoresistive elements of a second branch of the second full-bridge circuit are arranged at the distance apart, wherein the second field direction is perpendicular to the first field direction.

Aspect 4: The position sensor system as recited in Aspect 3, wherein the measuring direction runs in a plane which is spanned by the first field direction and the second field direction.

Aspect 5: The position sensor system as claimed in any of Aspects 1-4, wherein the distance is greater than or equal to 0.8 mm.

Aspect 6: The position sensor system as claimed in any of Aspects 1-5, wherein the distance is parallel to the measuring direction.

Aspect 7: The position sensor system as claimed in any of Aspects 1-6, wherein the distance is perpendicular to the measuring direction.

Aspect 8: The position sensor system as claimed in any of Aspects 1-7, wherein a minimum distance between the magnet arrangement and the first sensor is greater than 0.5 mm.

Aspect 9: The position sensor system as claimed in any of Aspects 1-8, wherein the four magnetoresistive elements of the first sensor are arranged in a common housing.

Aspect 10: The position sensor system as claimed in any of Aspects 1-9, wherein the magnet arrangement comprises a sintered ferrite material.

Aspect 11: The position sensor system as recited in Aspect 3, wherein the first two magnetoresistive elements of the first branch of the first sensor are located substantially at a same position in the measuring direction as the first two magnetoresistive elements of the first branch of the second sensor.

Aspect 12: The position sensor system as claimed in any of Aspects 1-11, wherein the magnet arrangement consists of a single dipole magnet.

Aspect 13: The position sensor system as recited in Aspect 3, further comprising: an evaluation circuit configured to determine a relative position between the magnet arrangement and the first sensor in the measuring direction, based on a first measured value between the first branch and the second branch of the first full-bridge circuit of the first sensor and based on a second measured value between the first branch and the second branch of the second full-bridge circuit of the second sensor.

Aspect 14: A system configured to perform one or more operations recited in one or more of Aspects 1-13.

Aspect 15: An apparatus comprising means for performing one or more operations recited in one or more of Aspects 1-13.

1. A position sensor system, comprising:
a magnet arrangement having at least one north pole and one south pole; and
a first sensor spaced apart from the magnet arrangement, wherein the first sensor comprises four magnetoresistive elements interconnected in a first full-bridge circuit and sensitive to a first field direction, wherein a first two magnetoresistive elements of a first branch of the first full-bridge circuit are arranged at a distance apart of more than 0.5 mm and wherein a second two magnetoresistive elements of a second branch of the first full-bridge circuit are arranged at the distance apart;
wherein the magnet arrangement is movable relative to the first sensor in a measuring direction, or the first sensor is movable relative to the magnet arrangement in the measuring direction.

2. The position sensor system as claimed in claim 1, wherein the four magnetoresistive elements are based on a magnetic tunnel resistance.

3. The position sensor system as claimed in claim 1, further comprising:
a second sensor spaced apart from the magnet arrangement, wherein the second sensor comprises another four magnetoresistive elements interconnected in a second full-bridge circuit and sensitive to a second field direction, wherein a first two magnetoresistive elements of a first branch of the second full-bridge circuit are arranged at the distance apart and wherein a second two magnetoresistive elements of a second branch of the second full-bridge circuit are arranged at the distance apart, wherein the second field direction is perpendicular to the first field direction.

4. The position sensor system as claimed in claim 3, wherein the measuring direction runs in a plane which is spanned by the first field direction and the second field direction.

5. The position sensor system as claimed in claim 1, wherein the distance is greater than or equal to 0.8 mm.

6. The position sensor system as claimed in claim 1, wherein the distance is parallel to the measuring direction.

7. The position sensor system as claimed in claim 1, wherein the distance is perpendicular to the measuring direction.

8. The position sensor system as claimed in claim 1, wherein a minimum distance between the magnet arrangement and the first sensor is greater than 0.5 mm, greater than 0.8 mm or greater than 1.0 mm.

9. The position sensor system as claimed in claim 1, wherein the four magnetoresistive elements of the first sensor are arranged in a common housing.

10. The position sensor system as claimed in claim 1, wherein the magnet arrangement comprises a sintered ferrite material.

11. The position sensor system as claimed in claim 3, wherein the first two magnetoresistive elements of the first branch of the first sensor are located substantially at a same position in the measuring direction as the first two magnetoresistive elements of the first branch of the second sensor.

12. The position sensor system as claimed in claim 1, wherein the magnet arrangement consists of a single dipole magnet.

13. The position sensor system as claimed in claim 3, further comprising:
an evaluation circuit configured to determine a relative position between the magnet arrangement and the first sensor in the measuring direction, based on a first measured value between the first branch and the second branch of the first full-bridge circuit of the first sensor and based on a second measured value between the first branch and the second branch of the second full-bridge circuit of the second sensor.
